(19) United States
(12) Patent Application Publication
(10) Pub. No.: US 2010/0243029 A1
(43) Pub. Date: Sep. 30, 2010

(54) FLEXIBLE SOLAR CELL MODULE

(75) Inventors: Akio HIGASHI, Ashigarakami-gun (JP); Hiroshi Nagate, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/748,825

(22) Filed: Mar. 29, 2010

(30) Foreign Application Priority Data
Mar. 31, 2009 (JP) 084356/2009

(51) Int. Cl. H01L 31/042

(52) U.S. Cl. 136/244

(57) ABSTRACT

A flexible solar cell module that includes a flexible insulating substrate; a plurality of photoelectric conversion elements formed on the substrate, each including a rear electrode layer, a photoelectric conversion layer, and a transparent electrode layer; an organic insulating protection film covering each photoelectric conversion element such that light transparency for each photoelectric conversion element is secured; and an inorganic insulating protection film provided on each transparent electrode layer such that light transparency on a light receiving side of each photoelectric conversion element is secured. The inorganic insulating protection film is formed to have a layer structure that includes a silicon oxynitride layer as the outermost layer of the structure. This enables improvement of the weather resistance and water vapor barrier properties and improvement of the photoelectric conversion efficiency of the solar cell module to be achieved at a low cost.

### BACKGROUND OF THE INVENTION

1. Field of the Invention

The present invention relates to a flexible solar cell module that includes a flexible insulating substrate on which a photoelectric conversion element having a laminated structure of a rear electrode layer, a photoelectric conversion layer, and a transparent electrode layer is provided.

2. Description of the Related Art

Currently, glass substrates are mainly used as solar cell substrates, but the use of flexible metal substrates has been studied. Solar cells with a metal substrate have a potential prospect to be applied to a wider range of applications in comparison with those that employ a glass substrate due to lightweight and flexibility of the substrate. Further, it is expected that photoelectric conversion characteristics and hence photoelectric conversion efficiency of solar cells will be improved because the metal substrate can withstand high temperature processing.

When a conductive substrate, such as a stainless steel plate, is used as the metal substrate, a solar cell module which is chemically stable and excellent in weather resistance (water resistance, moisture resistance, UV resistance, and the like) and water vapor barrier properties on the side opposite to the light receiving side may be produced. Consequently, as shown in FIG. 6, for example, a photoelectric conversion element is formed on a stainless steel substrate by stacking a rear electrode layer, a photoelectric conversion layer, and a transparent electrode layer on top of each other, and a transparent surface protection film of a fluorine resin is bonded with a transparent adhesive/filler on the light receiving side to improve the weather resistance and water vapor barrier properties of the solar cell module. Further, as shown in FIG. 7, a method in which a water vapor barrier film is disposed between a surface protection film and a transparent electrode layer via an adhesive/filler is also used in order to further improve the weather resistance and water vapor barrier properties of the solar cell module.

Still further, as shown in FIG. 8, another method for improving the weather resistance and water vapor barrier properties of a solar cell module is also proposed as described, for example, in Japanese Patent No. 3076895, in which a SiOₓ (x≧1) film is directly formed on a transparent electrode layer and a surface protection film is bonded on the SiOₓ film using an adhesive/filler.

The solar cell module shown in FIG. 6, however, is insufficient in weather resistance and water vapor barrier properties to completely prevent the ingress of water vapor, since the light receiving side is covered only by the surface protection film and adhesive/filler. The solar cell module shown in FIG. 7 has difficulties to reduce cost because the water vapor barrier film is expensive. Further, the solar cell module shown in FIG. 8 has a large difference in refractive index between the SiOₓ film and transparent electrode layer so that a portion of incident light is reflected at the interface between them, whereby the photoelectric conversion efficiency is degraded, though sufficient weather resistance and water vapor barrier properties may be ensured.

The present invention has been developed in view of the circumstances described above, and it is an object of the present invention to provide a solar cell module with improved weather resistance and water vapor barrier properties, and improved photoelectric conversion efficiency both achieved at a low cost by optically matching refractive indices of films disposed on the outer side of the transparent electrode layer.

### SUMMARY OF THE INVENTION

A solar cell module according to the present invention is a solar cell module, including:

a flexible insulating substrate;

a plurality of photoelectric conversion elements formed on the substrate, each including a rear electrode layer, a photoelectric conversion layer, and a transparent electrode layer;

a terminal for extracting a current or an electromotive force generated by a photoelectric conversion function of each photoelectric conversion element;

an organic insulating protection film covering each photoelectric conversion element such that light transparency for each photoelectric conversion element is secured;

a lead wire connecting each photoelectric conversion element and the terminal; and

an inorganic insulating protection film provided on each transparent electrode layer such that light transparency on a light receiving side of each photoelectric conversion element is secured,

wherein the inorganic insulating protection film has a layer structure that includes a silicon oxynitride layer as the outermost layer of the structure.

The term “layer structure” of the inorganic insulating protection film as used herein refers to a structure having one or more layers which are distinguishable based on the material compositions thereof. That is, if two layers are made of materials having the same constituent element but differ in composition, the layers are regarded as different layers. In an area in which the composition varies continuously, a clear distinction can not be made based on the composition, so that such area is regarded as one layer.

Preferably, in the flexible solar cell module of the present invention, the silicon oxynitride layer has a refractive index of 1.50 to 1.90.

Further, preferably, the layer structure includes a silicon nitride layer.

Preferably, the layer structure is a two-layer structure in which a silicon nitride layer and a silicon oxynitride layer are disposed on top of each other from the photoelectric conversion element side or a three-layer structure in which a silicon oxynitride layer, a silicon nitride layer, and a silicon oxynitride layer are disposed on top of each other from the photoelectric conversion element side.

Further, the layer structure may be a single layer structure of a silicon oxynitride layer, and the silicon oxynitride layer may be a layer formed so as to have a refractive index that continuously increases from the outermost side toward the photoelectric conversion element side.

Preferably, the organic insulating protection film is formed of a resin, which is a vinyl copolymer formed with ethylene as a co-monomer, having a refractive index of 1.35 to 1.50, and the transparent electrode layer is formed of aluminum and/or gallium doped zinc oxide having a refractive index of 1.90 to 2.00.

Preferably, the major component of the photoelectric conversion layer is at least one type of compound semiconductor having a chalcopyrite structure, and more preferably it is at least one type of compound semiconductor formed of a group Ib element, a group IIIb element, and a group VIb element.

Here, it is preferable that the group Ib element is at least one type of element selected from the group consisting of Cu and Ag; the group IIIb element is at least one type of element selected from the group consisting of Al, Ga, and In; and the group VIb element is at least one type of element selected from the group consisting of S, Se, and Te.

Element group representation herein is based on the short period periodic table. The term “major component” of the photoelectric conversion layer as used herein refers to a component included in the photoelectric conversion layer in an amount not less than 75% by mass.

The flexible solar cell module of the present invention includes, on the transparent electrode layer, an inorganic insulating protection film having a layer structure that includes a silicon oxynitride layer as the outermost layer of the structure. The refractive index of the silicon oxynitride (SiOₓN_{y}, x and y are not less than 1) can be adjustable from 1.46, which is the refractive index of silicon oxide (SiOₓ) to 2.00, which is the refractive index of silicon nitride (SiN_{y}). Accordingly, by optically matching the refractive indices between the organic insulating protection film and transparent electrode layer using the silicon oxynitride layer, reflection of incident light may be prevented and the photoelectric conversion efficiency of the module may be improved. Further, by providing the silicon oxynitride layer, which can be formed at a low cost and has high insulating properties, on the transparent electrode layer, the weather resistance and water vapor barrier properties of the module may be improved at a low cost without using a water vapor barrier film. Consequently, for the flexible solar cell module, both the improvement of weather resistance and water vapor barrier properties and the improvement of photoelectric conversion efficiency may be realized at a low cost.

### BRIEF DESCRIPTION OF THE DRAWINGS

FIG. 1 is a schematic cross-sectional view of a flexible solar cell module (integrated type) of the present invention.

FIG. 2 is a schematic cross-sectional view of a solar module according to a first embodiment, illustrating the layer structure thereof.

FIG. 3 is a schematic cross-sectional view of a flexible solar cell module (cell-strings connected type) of the present invention.

FIG. 4 is a schematic cross-sectional view of a solar module according to a second embodiment, illustrating the layer structure thereof.

FIG. 5 is a schematic cross-sectional view of a solar module according to a third embodiment, illustrating the layer structure thereof.

FIG. 6 is a schematic cross-sectional view of an example conventional solar cell module, illustrating the layer structure thereof (example 1).

FIG. 7 is a schematic cross-sectional view of an example conventional solar cell module, illustrating the layer structure thereof (example 2).

FIG. 8 is a schematic cross-sectional view of an example conventional solar cell module, illustrating the layer structure thereof (example 3).

FIG. 9 is a schematic cross-sectional view of a film structure that generates multiple reflections.

### DESCRIPTION OF THE PREFERRED EMBODIMENTS

Hereinafter, embodiments of the present invention will be described with reference to the accompanying drawings. It should be appreciated, however, that the invention is not limited to the embodiments. In the drawings, each component is not drawn to scale in order to facilitate visual recognition.

### Flexible Solar Cell Module

### First Embodiment of the Flexible Solar Cell Module

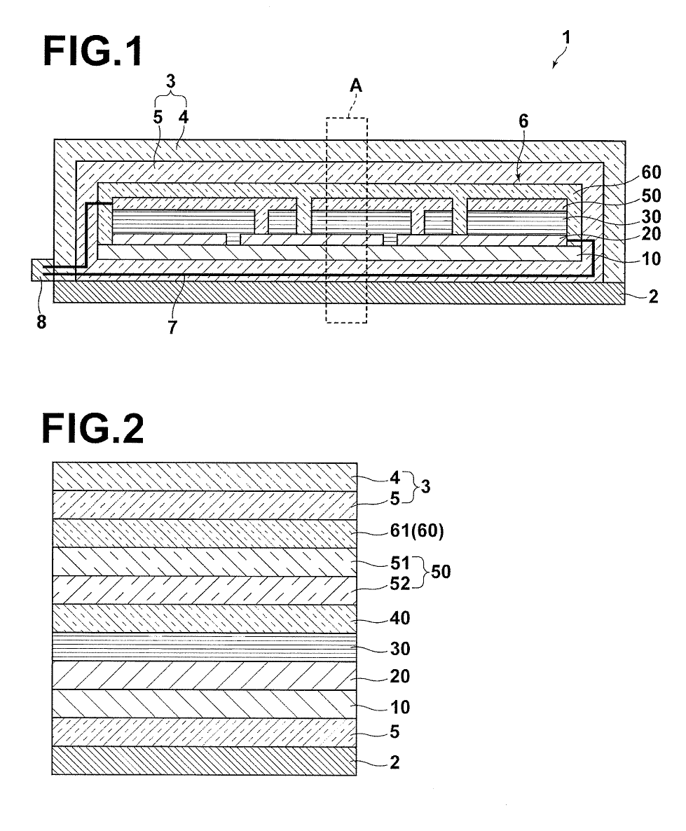

First, the structure of solar cell module 1 according to the first embodiment will be described. FIG. 1 is a schematic cross-sectional view of a flexible solar cell module (integrated type) of the present invention. FIG. 2 is a schematic cross-sectional view of the flexible solar cell module shown in FIG. 1, illustrating the layer structure in area A of the module.

As shown in FIG. 1, flexible solar cell module 1 includes back sheet 2, integrated solar cell 6, organic insulating protection film 3 constituted by adhesive/filler (encapsulation resin) 5 filling an area around solar cell 6 and surface protection film 4 covering over back sheet 2, terminal 8 for extracting a current or an electromotive force generated by solar cell 6, and lead wire 7 for guiding the current or electromotive force generated in solar cell 6 to terminal 8. As shown in FIG. 2, the specific layer structure of solar cell module 1 of the present embodiment includes surface protection film 4 (organic insulating protection film 3), adhesive/filler 5 (organic insulating protection film 3), silicon oxynitride layer 61 (inorganic insulating protection film 60), low resistance transparent electrode layer 51 (transparent electrode layer 50), high resistance transparent electrode layer 52 (transparent electrode layer 50), buffer layer 40, photoelectric conversion layer 30, rear electrode layer 20, flexible metal substrate 10, adhesive/filler 5, and back sheet 2 from the light receiving side of solar cell module 1. Note that transparent electrode layer 50 shown in FIG. 1 is depicted in more detail in FIG. 2 and shows that transparent electrode layer 50 includes low resistance transparent electrode layer 51 and high resistance transparent electrode layer 52. Further, FIG. 2 shows that buffer layer 40, which is omitted in FIG. 1, is disposed between photoelectric conversion layer 30 and high resistance transparent electrode layer 52.

(Back Sheet)

Back sheet 2 is a sheet for protecting solar cell 6 from the ambient environment and preventing deterioration of the cell. Back sheet 2 is integrally combined with adhesive/filler 5 after solar cell 6 is sealed with adhesive/filler 5. Back sheet 2 is required of weather resistance, water vapor barrier properties, electrical insulation properties, mechanical characteristics (tensile strength, stretching, tearing strength, and the like), chemical resistance, and the like, since the surface of back sheet 2 is exposed directly to the outdoor environment. Therefore, a fluorine resin film or a PET (polyethylene terephthalate) resin film is preferably used for back sheet 2 in order to satisfy these requirements. Further, the use of composite films made of several different materials is more preferable. Examples of such composite films include a PVF (polyvinyl fluoride)/adhesive/PET/adhesive/EVA (ethylene vinyl acetate), coating/PET/adhesive/EVA, coating/aluminum foil/adhesive/PET/adhesive/EVA, PET/adhesive/silica deposited PET/adhesive/EVA, and the like.

(Solar Cell)

Solar cell 6 is a basic structure of the solar cell module and includes a plurality of serially connected photoelectric conversion elements (each including layers from the substrate up to transparent electrode layer). Generally, the cell pitch and cell width of solar cell 6 are 3 to 10 mm and 100 to 1000 mm respectively. As shown in FIG. 1, solar cell 6 includes large area flexible metal substrate 10, rear electrode layer 20, photoelectric conversion layer 30, transparent electrode layer 50, and inorganic insulating protection film 60. Solar cell 6 has a plurality of grooves, whereby the cell is structured such that upper electrode 50 of a certain photoelectric conversion element is serially connected to lower electrode 20 of an adjacent photoelectric conversion element.

Large area flexible metal substrate 10 is a metal substrate with an anodized film (insulating oxide film) formed on a surface thereof by anodization. Such a metal substrate ensures high insulating properties. There is not any specific restriction on the material of the metal substrate and any material may be used as long as it is capable of providing an anodized film on a surface thereof by anodization. Specific examples of such materials include Al, Zr, Ti, Mg, Cu, Nb, Ta, alloys thereof, and the like. Among the materials, Al is particularly preferable from the viewpoint of cost and characteristics required of a solar cell. Flexible metal substrate 10 may have an anodized film on each surface or either one of the surfaces. Anodization may be performed by immersing a metal substrate, which is cleaned, smoothed by polishing, and the like as required, as an anode together with a cathode in an electrolyte, and applying a voltage between the anode and cathode. There is not any specific restriction on the thickness of the metal substrate. Although, an appropriate thickness of the metal substrate before anodization may be determined by stress calculation results based the mechanical strength of flexible metal substrate 10, reduction in thickness and weight, and material characteristics, it is preferable to be, for example, 0.05 to 0.6 mm and more preferably to be 0.1 to 0.3 mm. When providing flexible metal substrate 10, it is necessary to set the thickness of the material substrate to a value that allows for a lessening amount since the thickness is reduced by anodization and prior washing or polishing. Although, an appropriate thickness of the anodized film may be determined by stress calculation results based on insulating properties, mechanical strength and material characteristics of the substrate, it is preferable, for example, to be 0.1 to 100 μm.

When the anodized film has fine pores, any known pore sealing process may be performed, as required. The pore sealing process may increase voltage resistance and insulating properties. Further, if the pores are sealed using a material containing an alkali metal, when photoelectric conversion layer 30 of CIGS or the like is annealed, the alkali metal, preferably Na, diffuses in photoelectric conversion layer 30, whereby the crystallization of photoelectric conversion layer 30, and hence photoelectric conversion efficiency, may sometimes be improved. The manufacturing process of flexible substrate 10 may include various optional steps as well as essential steps. Examples of such optional steps include, for example, a degreasing step for removing rolling oil, a desmutting step for dissolving smuts on the surface of the metal substrate, a surface roughening step for roughening the surface of the metal substrate.

Rear electrode 20 and transparent electrode 50 are made of a conductive material. Transparent electrode 50 on the light input side needs to be transparent. For example, Mo may be used as a material of rear electrode 20. Preferably, the thickness of rear electrode 20 is not less than 100 nm, and more preferably in the range from 0.4 to 1.0 μm. There is not any specific restriction on the method of forming rear electrode 20, and vapor deposition methods, such as electron beam evaporation and sputtering may be used. Examples of preferable major components of transparent electrode 50 include ZnO, ITO, SnO₂, and combinations thereof. More preferably, transparent electrode layer 50 is formed of aluminum and/or gallium doped zinc oxide having a refractive index of 1.90 to 2.00 from the viewpoint that it (N-type) allows junction formation with a photoelectric conversion layer (P-type) of CIGS or the like and cost reduction. Transparent electrode layer 50 may have a single layer structure or a laminated structure, such as a two-layer structure or the like. There is not any specific restriction on the thickness of transparent electrode layer 50, and a value in the range from 0.1 to 1 μm is preferably used. Preferably, a buffer layer is provided between photoelectric conversion layer 30 and transparent electrode layer 50. As for buffer layer 40, CdS, ZnS, InS, ZnO, ZnMgO, ZnS(O, OH), or a combination thereof is preferably used. Preferably, the thickness of buffer layer is 10 to 50 nm.

Photoelectric conversion layer 30 is a layer that generates a current by absorbing light. There is not any specific restriction on the major component of the layer, and preferably the major component includes at least one type of compound semiconductor having a chalcopyrite structure. Preferably, the major component of photoelectric conversion layer 30 includes at least one type of compound semiconductor formed of a group Ib element, a group IIIb element, and a group VIb element.

As having a high light absorption rate and providing high photoelectric conversion efficiency, it is preferable that the major component of the photoelectric conversion layer is at least one type of compound semiconductor formed of at least one type of group Ib element selected from the group consisting of Cu and Ag, at least one type of group IIIb element selected from the group consisting of Al, Ga, and In, and at least one type of group VIb element selected from the group consisting of S, Se, and Te.

Examples of such compound semiconductors described above include CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ) Se₂ (CIGS), Cu(In₁₋ₓAlₓ) Se₂, Cu(In₁₋ₓGaₓ)(S, Se)₂, Ag(In₁₋ₓGaₓ)Se₂, Ag(In₁₋ₓGaₓ)(S, Se)₂, and the like.

It is particularly preferable that the photoelectric conversion semiconductor layer includes CuInSe₂ (CIS) and/or a compound dissolved with Ga, i.e, Cu (In, Ga) Se₂ (CIGS). CIS and CIGS are semiconductors having a chalcopyrite structure and are reported to have a high light absorption rate and high energy conversion efficiency. Further, they are excellent in the durability with less deterioration in the conversion efficiency due to light exposure and the like. CIGS layer may be formed by multi-source simultaneous deposition, selenization, sputtering, hybrid sputtering, or mechano-chemical process. Preferably, the thickness of photoelectric conversion layer is 500 to 5000 nm.

A preferable combination of the compositions for rear electrode layer 20, photoelectric conversion layer 30, buffer layer 40, and transparent electrode layer 50 is, for example, a Mo rear electrode layer/a CIGS photoelectric conversion layer/a CdS buffer layer/a ZnO transparent electrode layer.

Inorganic insulating protection film 60 is formed on transparent electrode layer 50 so as to secure transparency. FIG. 1 illustrates that inorganic insulating protection film 60 is formed also on the side faces of rear electrode layer 20, photoelectric conversion layer 30, and transparent electrode layer 50, but the portion of inorganic insulating protection film 60 on the side faces is not necessarily required. Inorganic insulating protection film 60 has a layer structure that includes a silicon oxynitride (SiOₓN_{y}, x and y are not less than 1) layer as the outermost layer from the viewpoint of manufacturing cost, weather resistance, water vapor barrier properties, and refractive index. Preferably, the layer thickness of the silicon oxynitride layer is 50 to 2000 nm if it has a single layer structure. Preferably, the refractive index of the silicon oxynitride layer is 1.5 to 1.90 from the viewpoint of the refractive index of organic insulating protection film 3 (surface protection film 4 and adhesive/filler 5). Preferably, the layer structure described above includes a silicon oxynitride layer from the viewpoint of further improvement in weather resistance and water vapor barrier properties.

There is not any specific restriction on the method of forming inorganic insulating film 60, but preferably it is formed by plasma enhanced chemical vapor deposition (PECVD). For PECVD, a low-temperature plasma generator, such as DC plasma, low-frequency plasma, high frequency (RF) plasma, pulsed plasma, tripolar plasma, microwave plasma, downstream plasma, columnar plasma, plasma assisted epitaxy, or the like may be used. From the viewpoint of plasma stability, the high frequency (RF) plasma is used more preferably. Example raw gases for use in PECVD include vaporized simple organic silane monomers, such as silane (SiH₄), disilane (Si₂H₆) hexamethyldisiloxane (HMDSO), tetramethylsilane (TMS), hexamethyldisilane, tetramethoxysilane (TMOS), tetraethoxysilane (TEOS), and the like or mixed gases thereof, and mixed gases of O₂, N₂, Ar, He, H₂, NO₂, NH₃ gases and the like. The raw gases described above is plasmatized by the method described above and deposited on transparent electrode layer 50, whereby a silicon oxynitride layer or silicon nitride layer of inorganic insulating protection film 60 is formed.

(Other Layers)

Solar cell 6 or the photoelectric conversion element may further include, as required, any layer other than those described above. For example, a close contact layer (buffer layer) may be provided, as required, between flexible metal substrate 10 and rear electrode 20 and/or between rear electrode 20 and photoelectric conversion layer 30 for enhancing the adhesion of the layers. Further, an alkali barrier layer may be provided between flexible metal substrate 10 and rear electrode 20 for preventing diffusion of alkali ions. For details of alkali barrier layer, refer to U.S. Pat. No. 5,626,688.

(Organic Insulating Protection Film)

Organic insulating protection film 3 includes adhesive/filler 5 filling an area around large area solar cell 6 and surface protection film 4 covering over back sheet 2. Preferably, organic insulating protection film 3 is formed of a resin, which a vinyl copolymer formed with ethylene as a co-monomer, having a refractive index of 1.35 to 1.50. More specifically, adhesive/filler 5 is one of such members and required to function as an adhesive and to protect solar cell 6 from external shocks, and EVA, PVB (polyvinyl butyral), and silicon resins may be used. Preferably, the thickness of adhesive/filler 5 is 50 to 1000 μm. From the viewpoint of transparency, weather resistance, adhesiveness, water vapor barrier properties, shock resistance, and the like, ETFE (ethylene tetrafluoroethylene copolymer) is preferably used for surface protection film 4. Preferably, the thickness of surface protection film 4 is 10 to 100 μm. Adhesive/filler 5 and surface protection film 4 are bonded by a vacuum laminating machine after solar cell 6 is formed.

(Terminal and Lead Wire)

Terminal 8 allows electrical connection to an external device, thereby allowing a current or electromotive force produced by the photoelectric conversion function to be extracted to the external device. Lead wire 7 is a wire for guiding the current or electromotive force generated in solar cell 6 to terminal 8.

An operation of solar cell module 1 of the present embodiment will now be described. In order to improve the photoelectric conversion efficiency of solar cell module 1, it is necessary to prevent reflection of incident light at each layer of solar cell 6 by selecting optimum values for the refractive index and layer thickness of each layer. Assuming that refractive indices of the layers from the light incident side as n₂, n₁, and n₀ and the layer thickness of the target layer as d₁, as shown in FIG. 9, energy reflection coefficient R₂₀, when multiple reflection is taken into account, is represented by Formula (1) below.

R₂₀=(n₀n₂−n₁²)²/n₀n₂+n₁²)² (1)

Here, when n₁=(n₀n₂)^{1/2}, selection of λ/4 as layer thickness d₁ causes the target layer to be non-reflective. Therefore, for example, if adhesive/filler 5 is formed of EVA (refractive index: 1.48), and low resistance transparent electrode layer 51 is formed of aluminum doped zinc oxide (refractive index: 2.00), non-reflective state may be obtained by setting the refractive index of silicon oxynitride layer 61 inserted between adhesive/filler 5 and low resistance transparent electrode layer 51 to (1.48×2.0)^{1/2}=1.72 and the layer thickness thereof to 250 nm with respect to λ=1000 nm. As the solar radiation is not monochromatic, the layer thickness of silicon oxynitride layer 61 is preferable to be 130 to 180 nm with respect to peak energy intensity of 500 to 700 nm.

As described above, flexible solar cell module 1 according to the present embodiment includes, on transparent electrode layer 50, inorganic insulating protection film 60 having a layer structure that includes silicon oxynitride layer 61 as the outermost layer. The refractive index of silicon oxynitride (SiOₓN_{y}, x and y are not less than 1) can be adjustable from 1.46, which is the refractive index of silicon oxide (SiOₓ) to 2.00, which is the refractive index of silicon nitride (SiN_{y}). Accordingly, by optically matching the refractive indices between organic insulating protection film 3 and transparent electrode layer 50 using silicon oxynitride layer 61, reflection of incident light may be prevented and the photoelectric conversion efficiency of the module may be improved. Further, by providing silicon oxynitride layer 61, which can be formed at a low cost and has high insulating properties, on transparent electrode layer 50, the weather resistance and water vapor barrier properties of the module may be improved at a low cost without using a water vapor barrier film. Consequently, for a flexible solar cell module, both the improvement of weather resistance and water vapor barrier properties and the improvement of photoelectric conversion efficiency may be realized at a low cost.

(Design Change of First Embodiment)

In the embodiment above, the description has been made of a case in which silicon oxynitride layer 61 is formed such that the entire layer has the same composition, but the present invention is not limited to this. That is, silicon oxynitride layer 61 may be formed such that the composition thereof varies continuously. In this case, silicon oxynitride layer 61 is formed so as to have a refractive index that continuously increases from the outermost side toward photoelectric conversion element side. In doing so, the optical matching of the refractive indices between organic insulating protection film 3 and transparent electrode layer 50 may further be improved. Where the layer structure of inorganic insulating protection film 60 includes a plurality of silicon oxynitride layers, the same applies to each silicon oxynitride layer.

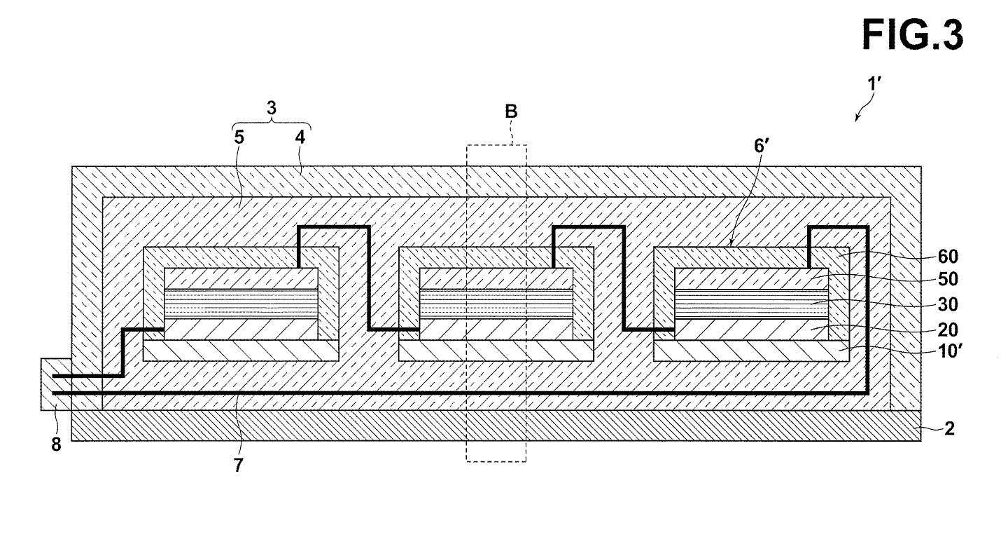

The flexible solar cell module of the present invention is not limited to the integrated type shown in FIG. 1 and the invention is applicable to a cell-strings connected module shown in FIG. 3. The cell-strings connected module shown in FIG. 3 differs from the integrated module shown in FIG. 1 in that it includes a plurality of solar cells 6′, each having flexible substrate 10′, instead of large area solar cell 6 shown in FIG. 1 and that they are connected in series by lead wire 7. In FIG. 3, other components identical to those in FIG. 1 are given the same reference numerals.

Flexible solar cell module 1′ includes back sheet 2, a plurality of solar cells 6′ disposed over back sheet 2, organic insulating protection film 3 constituted by adhesive/filler (encapsulation resin) 5 filling an area around the plurality of solar cells 6′ and surface protection film 4 covering over back sheet 2, terminal 8 for extracting a current or an electromotive force generated by solar cells 6′, and lead wire 7 for connecting the plurality of solar cells 6′ and guiding the current or electromotive force generated by solar cells 6′ to terminal 8. As shown in FIG. 3, solar cell 6′ includes flexible metal substrate 10′, rear electrode layer 20, photoelectric conversion layer 30, transparent electrode layer 50, and inorganic insulating protection film 60. In the cell-strings connected module constructed in the manner as described above, the present invention may be applied as in the first embodiment by paying attention to the layer structure in area B.

### Second Embodiment of Flexible Solar Cell Module

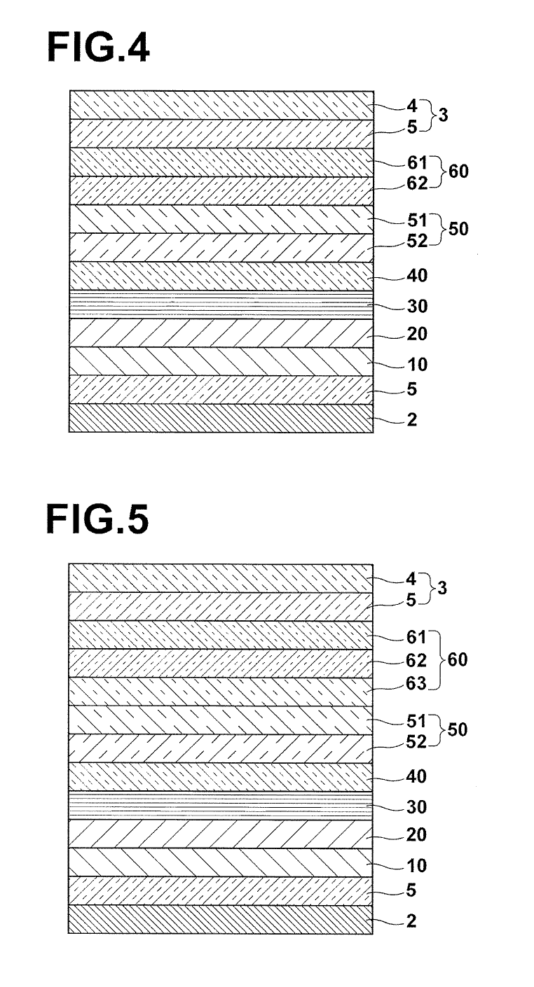

The structure of the flexible solar cell module of the present embodiment will be described first. The flexible solar cell module of the present embodiment differs from the flexible solar cell module of the first embodiment in that inorganic insulating protection film 60 has a two-layer structure in which silicon nitride layer 62 and silicon oxynitride layer 61 are disposed from the side of the photoelectric conversion element. Thus, the overall structure of the solar cell module of the present embodiment is similar to that described in the first embodiment and shown in FIG. 1. FIG. 4 is a schematic cross-sectional view of the solar cell module according to the present embodiment illustrating the layer structure thereof.

That is, as shown in FIG. 4, the specific layer structure of the solar cell module of the present embodiment includes surface protection film 4 (organic insulating protection film 3), adhesive/filler 5 (organic insulating protection film 3), silicon oxynitride layer 61 (inorganic insulating protection film 60), silicon nitride layer 62 (inorganic insulating protection film 60), low resistance transparent electrode layer 51 (transparent electrode layer 50), high resistance transparent electrode layer 52 (transparent electrode layer 50), buffer layer 40, photoelectric conversion layer 30, rear electrode layer 20, flexible metal substrate 10, adhesive/filler 5, and back sheet 2 from the light receiving side of solar cell module.

Silicon nitride layer 62 has high weather resistance and water vapor barrier properties, and is excellent as an insulating protection film. Silicon nitride layer 62, however, has degraded transparency on short wavelength side (400 nm or less). Further, the layer has a large film stress which gives stress to underlying transparent electrode layer 50, photoelectric conversion layer, and the like and causes problems of performance degradation, film detachment, cracks, and the like. Thus, it is preferable to make silicon nitride layer 62 as thin as possible and a preferable range of the thickness is from 50 to 1000 nm. In this case, a preferable range of the thickness of silicon oxynitride layer 61 is from 50 to 1000 nm.

As described above, also the flexible solar cell module according to the present embodiment includes, on transparent electrode layer 50, inorganic insulating protection film 60 having a layer structure that includes silicon oxynitride layer 61 as the outermost layer. Accordingly, by optically matching the refractive indices between organic insulating protection film 3 and transparent electrode layer 50, reflection of incident light may be prevented, whereby the photoelectric conversion efficiency may be improved. Further, the weather resistance and water vapor barrier properties of the module may be improved at a low cost without using a water vapor barrier film. Consequently, advantageous effects identical to those of the first embodiment may be obtained. In addition, provision of silicon nitride layer 62 may further improve the weather resistance and water vapor barrier properties of the module at a low cost.

### Third Embodiment of Flexible Solar Cell Module

The structure of the flexible solar cell module of the present embodiment will be described first. The flexible solar cell module of the present embodiment differs from the flexible solar cell module of the first embodiment in that inorganic insulating protection film 60 has a three-layer structure in which silicon oxynitride layer 63, silicon nitride layer 62, and silicon oxynitride layer 61 are provided from the side of the photoelectric conversion layer. Thus, the overall structure of the solar cell module of the present embodiment is similar to that described in the first embodiment and shown in FIG. 1. FIG. 5 is a schematic cross-sectional view of the solar cell module according to the present embodiment illustrating the layer structure thereof.

That is, as shown in FIG. 5, the specific layer structure of the solar cell module of the present embodiment includes surface protection film 4 (organic insulating protection film 3), adhesive/filler 5 (organic insulating protection film 3), silicon oxynitride layer 61 (inorganic insulating protection film 60), silicon nitride layer 62 (inorganic insulating protection film 60), silicon oxynitride layer 63 (inorganic insulating protection film 60), low resistance transparent electrode layer 51 (transparent electrode layer 50), high resistance transparent electrode layer 52 (transparent electrode layer 50), buffer layer 40, photoelectric conversion layer 30, rear electrode layer 20, flexible metal substrate 10, adhesive/filler 5, and back sheet 2 from the light receiving side of solar cell module.

Silicon nitride layer 62 has high weather resistance and is excellent as an insulating protection film. As described above, however, silicon nitride layer 62 has a large film stress which gives stress to underlying transparent electrode layer 50, photoelectric conversion layer, and the like and causes problems of performance degradation, film detachment, cracks, and the like. Consequently, in the present embodiment, silicon oxynitride layer 63 is further provided between silicon nitride layer 62 and transparent electrode layer 50 in order to reduce the influence of silicon nitride layer 62 on transparent electrode layer 50 and photoelectric conversion layer 30. In this case, a preferable range of the thickness of each of silicon oxynitride layers 61 and 63 is from 50 to 500 nm.

As described above, also the flexible solar cell module according to the present embodiment includes, on the transparent electrode layer, the inorganic insulating protection film having a layer structure that includes the silicon oxynitride layer as the outermost layer. Accordingly, by optically matching the refractive indices between organic insulating protection film 3 and transparent electrode layer 50, reflection of incident light may be prevented, whereby the photoelectric conversion efficiency may be improved. Further, the weather resistance and water vapor barrier properties of the module may be improved at a low cost without using a water vapor barrier film. Consequently, advantageous effects identical to those of the first embodiment may be obtained. In addition, provision of silicon nitride layer 62 may further improve the weather resistance and water vapor barrier properties of the module at a low cost. Further, provision of silicon oxynitride layer 63 between silicon nitride layer 62 and transparent electrode layer 50 may reduce the influence of silicon nitride layer 62 on transparent electrode layer 50, photoelectric conversion layer, and the like, whereby a stable flexible solar cell module may be manufactured.

### EXAMPLES

Specific examples of the present embodiment will now be described in detail. Comparison of water vapor transmission rates was made among Example 1, Example 2, and Comparative Example 1.

### Example 1

A base body of a solar cell having layers up to a transparent electrode layer is mounted in a PECVD system. After the overall pressure of the system was set to 1×10⁻³ Pa, a mixed gas of SiH₄:NH₃:N₂:N₂O=1:20:30:10 was supplied to the film forming chamber of the system, whereby the pressure of the chamber became 6.6×10 Pa. At the same time, a voltage having a high frequency (RF) of 13.56 MHz which is higher than that of the high voltage power source was applied to the electrode with a power of 500 W to generate plasma. The substrate temperature was 250° C., and film forming was performed for 500 seconds with a film forming speed of 2 nm/s to form a SiON film having a thickness of 1000 nm. The refractive index of the film was adjusted to 1.70. Then, after applying a 300 nm thick adhesive/filler film (EVA) and a 50 μm thick surface protection film (ETFE) on the light receiving side, and a 300 nm thick adhesive/filler film (EVA) and a back sheet on the flexible metal substrate side, thermocompression bonding was performed at 150° C. to thermocompression bond them using a vacuum laminating machine. In this way, a flexible solar cell module having a layer structure identical to that shown in FIG. 2 was obtained.

### Example 2

A base body of a solar cell having layers up to a transparent electrode layer is mounted in a PECVD system. After the overall pressure of the system was set to 1×10⁻³ Pa, a mixed gas of SiH₄:NH₃:N₂:N₂O=1:20:30:10 was supplied to the film forming chamber of the system, whereby the pressure of the chamber became 6.6×10 Pa. At the same time, a voltage having a high frequency (RF) of 13.56 MHz which is higher than that of the high voltage power source was applied to the electrode with a power of 500 W to generate plasma. The substrate temperature was 250° C., and film forming was performed for 100 seconds with a film forming speed of 2 nm/s to form a SiON film having a thickness of 200 nm. Then, a SiN film having a thickness of 300 nm was formed with a mixed gas of SiH₄:NH₃:N₂=1:20:30 under the same conditions, and further a SiON film having a thickness of 200 nm was formed under the same conditions, whereby an inorganic insulating protection film having a three-layer structure was obtained. The refractive indices of the layers were adjusted to 1.70, 2.00, and 1.90 respectively. Then, after applying a 300 nm thick adhesive/filler film (EVA) and a 50 μm thick surface protection film (ETFE) on the light receiving side, and a 300 nm thick adhesive/filler film (EVA) and a back sheet on the flexible metal substrate side, thermocompression bonding was performed at 150° C. to thermocompression bond them using a vacuum laminating machine. In this way, a flexible solar cell module having a layer structure identical to that shown in FIG. 5 was obtained.

### Comparative Example 1

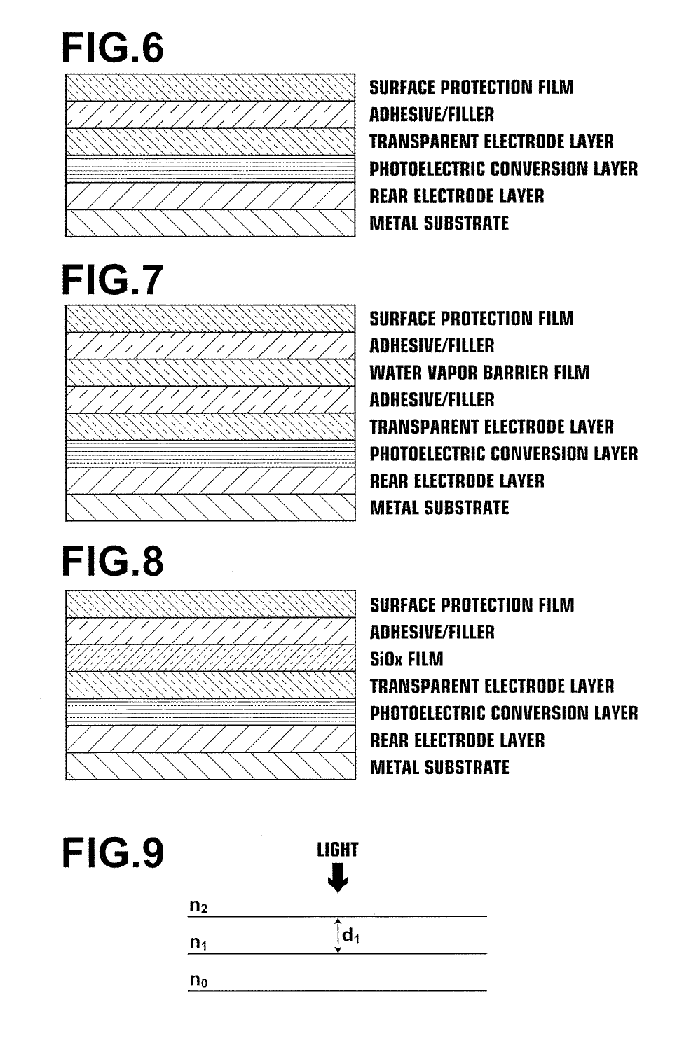

With respect to a base body of a solar cell having layers up to a transparent electrode layer, after applying a 300 nm thick adhesive/filler film (EVA) and a 50 μm thick surface protection film (ETFE) on the light receiving side, and a 300 nm thick adhesive/filler film (EVA) and a back sheet on the flexible metal substrate side, thermocompression bonding was performed at 150° C. to thermocompression bond them using a vacuum laminating machine. In this way, a flexible solar cell module having a layer structure identical to that shown in FIG. 6 was obtained.

### (Water Vapor Transmission Rate Measurements)

With respect to each solar cell module obtained in Example 1, Example 2, and Comparative Example 1, the water vapor transmission rate which is an index of water vapor barrier properties was measured. The water vapor transmission rate was measured by Mocon method using a water vapor transmission measuring equipment (PERMATRAN-W 3/31, manufactured by MOCON, U.S.) under a temperature of 40° C. and a humidity of 90% Rh.

### (Measurement Results)

Measurement results showed that the water vapor transmission rate of each solar cell module in Examples 1 and 2 was 10⁻² g/m²/day/atm or less. On the other hand, the water vapor transmission rate of the solar cell module in Comparative Example 1 was 5 g/m²/day/atm. This demonstrates that the solar cell module of the present invention may realize high water vapor barrier properties.

Next, comparison of photoelectric conversion efficiencies was made among Examples 3 to 5 and Comparative Example 2.

### Example 3

The flexible solar cell module obtained in Example 1 was used.

### Example 4

A base body of a solar cell having layers up to a transparent electrode layer is mounted in a PECVD system. After the overall pressure of the system was set to 1×10⁻³ Pa, a mixed gas of SiH₄:NH₃:N₂:N₂O=1:20:30:10 was supplied to the film forming chamber of the system, whereby the pressure of the chamber became 6.6×10 Pa. At the same time, a voltage having a high frequency (RF) of 13.56 MHz which is higher than that of the high voltage power source was applied to the electrode with a power of 500 W to generate plasma. The substrate temperature was 250° C., and film forming was performed for 100 seconds with a film forming speed of 2 nm/s to form a SiON film having a thickness of 200 nm. Then, a SiN film having a thickness of 300 nm was formed with a mixed gas of SiH₄:NH₃:N₂=1:20:30 under the same conditions, whereby an inorganic insulating protection film having a two-layer structure was obtained. The refractive indices of the two layers were adjusted to 1.70 and 2.00 respectively from the light receiving side. Then, after applying a 300 nm thick adhesive/filler film (EVA) and a 50 μm thick surface protection film (ETFE) on the light receiving side, and a 300 nm thick adhesive/filler film (EVA) and a back sheet on the flexible metal substrate side, thermocompression bonding was performed at 150° C. to thermocompression bond them using a vacuum laminating machine. In this way, a flexible solar cell module having a layer structure identical to that shown in FIG. 4 was obtained.

### Example 5

The flexible solar cell module obtained in Example 2 was used.

### Comparative Example 2

The flexible solar cell module obtained in Comparative Example 1 was used.

### (Photoelectric Conversion Efficiency Measurements)

With respect to each solar cell module of Examples 3 to 5 and Comparative Example 2, the photoelectric conversion efficiency was measured. The measurement was performed using a long pulse solar simulator for line testing under conditions of an irradiation intensity of AM 1.5 (100 mW/cm2), a temperature of 25° C., and a light irradiation time of 500 ms.

### (Measurement Results)

The measurement results are summarized in Table 1. The results showed that the photoelectric conversion efficiencies of the solar cell modules in Examples 3 to 5 and Comparative Example 2 were 13.7%, 14.0%, 14.2%, and 13.0% respectively. This demonstrates that the photoelectric conversion efficiency may be improved by applying the present invention and optically matching the refractive indices.

TABLE 1

| | Example 3 | Example 4 | Example 5 | C/Example 2 |
|---|---|---|---|---|
| Structure | One Layer | Two Layers | Three Layers | W/O Inorganic |
| | SiON | SiON/SiN | SiON/ | Insulating |
| | | | SiN/SiON | P/Film |
| P/E conversion | 13.7 | 14.0 | 14.2 | 13.0 |
| Efficiency (%) | | | | |

What is claimed is:

1. A flexible solar cell module, comprising:
a flexible insulating substrate;
a plurality of photoelectric conversion elements formed on the substrate, each including a rear electrode layer, a photoelectric conversion layer, and a transparent electrode layer;
a terminal for extracting a current or an electromotive force generated by a photoelectric conversion function of each photoelectric conversion element;
an organic insulating protection film covering each photoelectric conversion element such that light transparency for each photoelectric conversion element is secured;
a lead wire connecting each photoelectric conversion element and the terminal; and
an inorganic insulating protection film provided on each transparent electrode layer such that light transparency on a light receiving side of each photoelectric conversion element is secured,
wherein the inorganic insulating protection film has a layer structure that includes a silicon oxynitride layer as the outermost layer of the structure.

2. The flexible solar cell module of claim 1, wherein the silicon oxynitride layer has a refractive index of 1.50 to 1.90.

3. The flexible solar cell module of claim 1, wherein the layer structure includes a silicon nitride layer.

4. The flexible solar cell module of claim 2, wherein the layer structure includes a silicon nitride layer.

5. The flexible solar cell module of claim 1, wherein the layer structure is a two-layer structure in which a silicon nitride layer and a silicon oxynitride layer are disposed on top of each other from the photoelectric conversion element side.

6. The flexible solar cell module of claim 2, wherein the layer structure is a two-layer structure in which a silicon nitride layer and a silicon oxynitride layer are disposed on top of each other from the photoelectric conversion element side.

7. The flexible solar cell module of claim 1, wherein the layer structure is a three-layer structure in which a silicon oxynitride layer, a silicon nitride layer, and a silicon oxynitride layer are disposed on top of each other from the photoelectric conversion element side.

8. The flexible solar cell module of claim 2, wherein the layer structure is a three-layer structure in which a silicon oxynitride layer, a silicon nitride layer, and a silicon oxynitride layer are disposed on top of each other from the photoelectric conversion element side.

9. The flexible solar cell module of claim 1, wherein:
the layer structure is a single layer structure of a silicon oxynitride layer; and
the silicon oxynitride layer is a layer formed so as to have a refractive index that continuously increases from the outermost side toward the photoelectric conversion element side.

10. The flexible solar cell module of claim 2, wherein:
the layer structure is a single layer structure of a silicon oxynitride layer; and
the silicon oxynitride layer is a layer formed so as to have a refractive index that continuously increases from the outermost side toward the photoelectric conversion element side.

11. The flexible solar cell module of claim 1, wherein the organic insulating protection film is formed of a resin, which is a vinyl copolymer formed with ethylene as a co-monomer, having a refractive index of 1.35 to 1.50.

12. The flexible solar cell module of claim 2, wherein the organic insulating protection film is formed of a resin, which is a vinyl copolymer formed with ethylene as a co-monomer, having a refractive index of 1.35 to 1.50.

13. The flexible solar cell module of claim 1, wherein the transparent electrode layer is formed of aluminum and/or gallium doped zinc oxide having a refractive index of 1.90 to 2.00.

14. The flexible solar cell module of claim 2, wherein the transparent electrode layer is formed of aluminum and/or gallium doped zinc oxide having a refractive index of 1.90 to 2.00.

15. The flexible solar cell module of claim 11, wherein the transparent electrode layer is formed of aluminum and/or gallium doped zinc oxide having a refractive index of 1.90 to 2.00.

16. The flexible solar cell module of claim 12, wherein the transparent electrode layer is formed of aluminum and/or gallium doped zinc oxide having a refractive index of 1.90 to 2.00.

17. The flexible solar cell module of claim 1, wherein the major component of the photoelectric conversion layer is at least one type of compound semiconductor having a chalcopyrite structure.

18. The flexible solar cell module of claim 17, wherein the major component of the photoelectric conversion layer is at least one type of compound semiconductor formed of a group Ib element, a group IIIb element, and a group VIb element.

19. The flexible solar cell module of claim 18, wherein:
the group Ib element is at least one type of element selected from the group consisting of Cu and Ag;
the group IIIb element is at least one type of element selected from the group consisting of Al, Ga, and In; and
the group VIb element is at least one type of element selected from the group consisting of S, Se, and Te.
